(19) United States
(12) Patent Application Publication
(10) Pub. No.: US 2007/0031989 A1
(43) Pub. Date: Feb. 8, 2007

(54) Separating semiconductor wafers having exposed micromechanical structures into individual chips

(76) Inventors: Roy Knechtel, Geraberg (DE); Jutta Heller, Erfurt (DE); Gunnar Lindemann, Erfurt (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(21) Appl. No.: 10/546,816

(22) PCT Filed: Feb. 24, 2004
(86) PCT No.: PCT/DE04/00337

§ 371 Date: Aug. 28, 2006

(30) Foreign Application Priority Data
Feb. 27, 2003 (DE) 103 08 860.1

(51) Int. Cl. H01L 21/00

(52) U.S. Cl. 438/68; 438/464; 438/465

(57) ABSTRACT

The inventive method enables chips (1) to be separated without damaging them, which have exposed sensitive micromechanical structures, from the group of wafers by means of standard parting-off grinding processes. During the parting-off grinding process, the micromechanical structures are covered with a thermofilm (4) thereby protecting them. The parting-off grinding, referred to as cutting (6) for short, ensues from the front side of the wafer with the aid of cutting marks (5) on the wafer. During this, the protective film (4) is completely cut through. After cutting, heat is used to detach the protective film from the separated chips (8) without leaving remnants thereon and without force acting upon the micromechanical structures. The separated chips are held by a supporting film onto which the semiconductor wafer is drawn before the cutting step (6). The properties of the supporting film are not modified during the heat treatment of the protective film.

The separation of chips from the wafer composite by means of a parting-off grinding process (hereinafter referred to as dicing or cutting), is a standard process step during the manufacturing of microelectronic devices. Mainly, commercially available tools are used for this purpose, in which a water jet is directed at a saw blade. This jet serves two purposes: on the one hand, the saw blade is cooled by the water (dissipation of the frictional heat created during the dicing) so as to increase its durability, and, on the other hand, the saw dust is carried away by the water jet so that it may not accumulate on the diced chips and may not contaminate the chips. With this method, high dicing speeds may be achieved. The separated chips are supported by a carrier film, onto which a semiconductor wafer is drawn prior to the dicing.

This standard dicing procedure is, however, not appropriate for the separation of chips having exposed micromechanical structures, since the water jet may mechanically destroy the structures. For this reason, frequently micromechanical structures are capped, that is, prior to the separation, within the wafer composite (wafer bonding). Hereby, the chips receive a protective cap, which protects sensitive areas from mechanical impacts, cf. US-A-2002/0094662. Since this cap may not be removed from the chips after the dicing, this protecting procedure may not be appropriate for all applications of a microsystem technology. Very frequently, it is necessary that the exposed structures be non-covered, since they have to exchange information with the environment by means of specific housings. For the separation of such chips having exposed micromechanical structures, up to now, no universally applicable methods are known. In the research (covering the structures by means of photoresists and hashing the same after the dicing), as well as in the industry (dicing within a water bath), such approaches are known which allow an effective protection of the structures, which, however, bring about the contamination of the chips (resist residuals/saw dust), thereby negatively affecting the functionality and the lifetime of the structures. Therefore, in practice, these methods are not appropriate. US-A-2002/0096743 discloses—instead of a thermofilm—an intrinsically rigid cap which assists in supporting the chip until the end of the procedure.

It is an object of the present invention to simplify the separation process of semiconductor wafers having sensitive micromechanical structures, thereby reducing production costs.

The object of the present invention resides in the fact that sensitive micromechanical structures are to be protected with respect to contamination and damage during the separation of the semiconductor wafer into chips.

This object is solved by the present invention in that the semiconductor wafer having the micromechanical structures (1) is initially covered by a thermofilm (4) across the entire surface of the front side, that is, on the side on which the micromechanical structures are located, prior to the separation, for which purpose, for instance, commercially available films, may be used. Thereafter, the semiconductor wafer is drawn onto the standard dicing film (2), which is supported and clamped by a dicing frame (3), after which a dicing is performed from the front side by using a standard saw blade (6). Hereby, it is diced through the thermofilm.

Standard dicing parameters may be used, thereby enabling high dicing speeds and, thus, short dicing times.

The alignment of the dicing cuts is performed on the basis of dicing marks (5) on the wafer front side. To this end, the thermofilm is sufficiently transparent. The dicing slits (7) created in this way separate the wafer into chips (8), which are still covered all over and, thus, protected by the thermofilm.

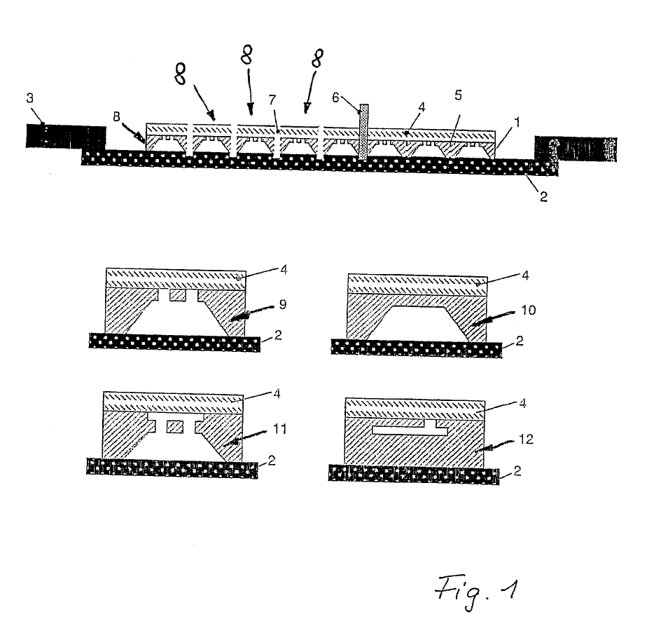

For a more detailed description, an example of FIG. 1 may be referred to.

After completion of the dicing or cutting process, the wafers are cleaned by water and are dried so as to remove saw dust from the film surfaces and from the dicing slits. Thereafter, the entire assembly is heated up to the conversion temperature of the thermofilm at which the adhesion of the thermofilm has completely vanished and at which the pieces of the film are removed from the chips due to the inherent stresses of the film. The removal of the film occurs without remnants and virtually without any force acting upon the structures to be protected, so that they are neither contaminated nor damaged.

By tilting the assembly, the pieces of the film drop away from the chips.

The present invention provides the advantage that standard process steps used in the field of microelectronic may be used for the drawing up of the film and for the dicing of the semiconductor wafers. Moreover, a re-clamping of the chips after the dicing is not necessary. After the removal of the thermofilm, a standard assembly is obtained, which may be processed by means of standard assembly processes (pick and place).

The method may be applied to structures, which may be fabricated by means of commonly used technologies employed in the field of micromechanics:

volume micromechanic structures having exposed or freely moveable structures (9),

volume micromechanic membrane structures (10),

surface micromechanical structures (12),

recessed structures within surface and/or bulk micromechanics (11).

### TABLE OF REFERENCE SIGNS

1. MEMS wafer to be diced
2. standard cutting or dicing film
3. dicing frame
4. thermofilm
5. cutting or dicing marks
6. standard saw blade
7. dicing slits
8. separated MEMS chip
9. chip volume micromechanics having exposed/freely movable structures
10. chip volume micromechanics having a membrane structure
11. chip volume micromechanics having recessed exposed/freely movable structures
12. chip surface micromechanics having exposed/freely movable structures.

We claim:

1. A method for separating semiconductor wafers having exposed micromechanical structures into chips by means of a parting-off grinding process, comprising the following process steps:
covering the semiconductor wafer all over on the front side, that is, on the side on which the micromechanical structures are located, by a thermofilm;
drawing up the semiconductor wafer onto a standard dicing film supported and clamped by a dicing frame (3) (semiconductor wafer assembly);
aligning the dicing cuts by means of dicing marks on the wafer front side, which may be viewed through the transparent thermofilm;
dicing, from the front side, by using a standard saw blade, wherein dicing is performed through the thermofilm;
cleaning the semiconductor wafer assembly;
drying the semiconductor wafer assembly;
heating the semiconductor wafer assembly up to the conversion temperature of the thermofilm, thereby completely compensating its adhesion force;
removing the thermofilm from the chips, for instance, by tilting the assembly.

2. The method of claim 1, further comprising further processing by a standard process.

3. A method for separating semiconductor wafers having exposed micromechanical structures into chips by means of a parting-off grinding process, during which the semiconductor wafer is clamped onto a standard dicing film that is supported by a dicing frame (3) (semiconductor wafer assembly), wherein the dicing cuts are aligned by dicing marks formed on the front side of the wafer, characterized in that
the semiconductor wafer is covered all over by means of a transparent thermofilm in a surface-sealed fashion with respect to the semiconductor wafer surface prior to drawing up the wafer onto the standard dicing film, said covering being performed on the front side of the wafer, that is, on the side, on which the micromechanical structures are located, wherein said thermofilm is cut through during the separation and is, after the separation process following the cleaning and drying, removed again from the chips by heating the assembly up to the conversion temperature of the thermofilm, thereby completely compensating the adhesion thereof, and by merely tilting the assembly.
